(19) United States
(12) Patent Application Publication
(10) Pub. No.: US 2026/0040875 A1
(43) Pub. Date: Feb. 5, 2026

(54) CARRIER BOAT, PROCESSING APPARATUS, AND METHOD FOR CONTROLLING PRESSURE DROP IN CARRIER BOAT

(71) Applicant: Jiangsu Leadmicro Nano-Technology Co.,Ltd., WUXI (CN)

(72) Inventors: Liu YANG, WUXI (CN); Baochen LIAO, WUXI (CN); Da YAN, WUXI (CN); Fangyu FAN, WUXI (CN)

(73) Assignee: Jiangsu Leadmicro Nano-Technology Co.,Ltd., WUXI (CN)

(21) Appl. No.: 19/355,411

(22) Filed: Oct. 10, 2025

Related U.S. Application Data
(63) Continuation of application No. PCT/CN2024/085518, filed on Apr. 2, 2024.

(30) Foreign Application Priority Data
Apr. 12, 2023 (CN) 202310389574.1

(51) Int. Cl. H01L 21/673; C23C 16/455

(52) U.S. Cl. CPC H01L 21/673; C23C 16/45557; C23C 16/45591

(57) ABSTRACT

A carrier boat includes a boat body and a front flow homogenizing plate. The boat body defines a placement chamber with openings at two opposite ends, and the placement chamber is configured to accommodate a plurality of to-be-processed components that are spaced apart. The front flow homogenizing plate is disposed in an opening of an end of the placement chamber of the boat body, so as to fill the opening of the placement chamber of the boat body. The front flow homogenizing plate includes a plurality of first blocking members that are spaced apart, and a first gap between two adjacent first blocking members is communicated with a second gap between two adjacent to-be-processed components. A processing apparatus and a method for controlling pressure drop in the carrier boat are further provided.

### CROSS-REFERENCE TO RELATED APPLICATIONS

The present application is a continuation of International Patent Application No. PCT/CN2024/085518, filed on Apr. 2, 2024, which claims priority to Chinese Patent Application No. 202310389574.1, entitled “A CARRIER BOAT, PROCESSING APPARATUS, AND METHOD FOR CONTROLLING PRESSURE DROP IN CARRIER BOAT”, filed on Apr. 12, 2023, both of which are herein incorporated by reference in their entirety.

### TECHNICAL FIELD

The present disclosure relates to the technical field of semiconductor device manufacturing, and in particular to a carrier boat, a processing apparatus, and a method for controlling pressure drop in the carrier boat.

### BACKGROUND

In the field of solar cell manufacturing, whether it is a passivated emitter and rear (PERC) cell or a tunnel oxide passivated contact (TOPCON) cell, in order to further improve photoelectric conversion efficiency of a monocrystalline silicon cell, a surface of the monocrystalline silicon cell is usually passivated. The purpose of passivation is to reduce recombination of non-equilibrium carriers caused by surface defects of a monocrystalline silicon wafer, which would otherwise affect the photoelectric conversion efficiency.

In order to prevent any loss in the photoelectric conversion efficiency, an aluminum oxide thin film is typically prepared on the surface of the monocrystalline silicon cell. Various atoms in the aluminum oxide thin film bond with dangling bonds on the surface of the monocrystalline silicon cell, which can reduce the influence of surface defects of the monocrystalline silicon on the carriers, thereby achieving a higher photoelectric conversion efficiency. The preparation of the aluminum oxide thin film usually involves an atomic layer deposition (ALD) device, and the ALD device is a device that deposits materials layer by layer in the form of a single atomic film on a surface of a substrate.

During the process, a reaction source is carried by nitrogen gas, and delivered into a spraying plate through a gas pipe from a source container. The spraying plate sprays reactive gas, the reactive gas flows through a carrier boat carrying the monocrystalline silicon cell sheets in an inner chamber. The process exhaust gas flows through the carrier boat carrying the monocrystalline silicon cell sheets, enters a pump pipe connected to a vacuum system, and flows out of the chamber. A stable inner chamber pressure, a stable temperature, a stable flow rate, and the gas stably flowing through the carrier boat carrying the monocrystalline silicon cell sheets, are conducive to ensuring uniformity and density of the deposited aluminum oxide thin film.

However, as a placement chamber becomes larger and more monocrystalline silicon cell sheets are loaded into the carrier boat, the excess reaction source directly enters the carrier boat carrying the monocrystalline silicon cell sheets from the spraying plate, which leads to localized areas with too much reaction source and some areas of the monocrystalline silicon cell sheets not receiving the aluminum oxide thin film deposition, thereby resulting in low photoelectric conversion efficiency.

### SUMMARY OF THE DISCLOSURE

The present disclosure provides a carrier boat including a boat body and a front flow homogenizing plate. The boat body defines a placement chamber with openings at two opposite ends, and the placement chamber is configured to accommodate a plurality of to-be-processed components that are spaced apart. The front flow homogenizing plate is disposed in an opening of an end of the placement chamber of the boat body, so as to fill the opening of the placement chamber of the boat body. The front flow homogenizing plate includes a plurality of first blocking members that are spaced apart, and a first gap between two adjacent first blocking members is communicated with a second gap between two adjacent to-be-processed components.

In some embodiments, the carrier boat further includes a rear flow homogenizing plate, the rear flow homogenizing plate is disposed in an opening on another end of the placement chamber of the boat body, and the rear flow homogenizing plate includes a plurality of second blocking members that are spaced apart.

In some embodiments, in a direction from the front flow homogenizing plate to the rear flow homogenizing plate, a width of the rear flow homogenizing plate is greater than that of the front flow homogenizing plate.

In some embodiments, the second blocking members are inclined relative to a plane where the to-be-processed components are located.

In some embodiments, the rear flow homogenizing plate includes a plurality of interconnected flow homogenizing sub-plates, and the second blocking members in any one of the plurality of flow homogenizing sub-plates have different density.

In some embodiments, density of the second blocking members in the rear flow homogenizing plate is disposed from dense at a center to sparse towards periphery.

In some embodiments, a width of a third gap between two adjacent second blocking members is greater than that of the second gap.

In some embodiments, a width of the second gap is less than that of the first gap.

In some embodiments, a plane where any one of the plurality of first blocking members is located is parallel to a plane where any one of plurality of to-be-processed components is located.

The present disclosure provides a processing apparatus including a spraying device and the above carrier boat, and the spraying device is disposed on a side of the front flow homogenizing plate in the carrier boat.

The present disclosure provides a method for controlling pressure drop in a carrier boat. In the method, density of the second blocking members, or a thickness of the rear flow homogenizing plate and a thickness of each second blocking member of the rear flow homogenizing plate in the above carrier boat is adjusted, so as to control pressure drop in the carrier boat.

### BRIEF DESCRIPTION OF THE DRAWINGS

In order to more clearly illustrate the technical solutions in some embodiments of the present disclosure or in the related art, hereinafter, a brief introduction will be given to the accompanying drawings that are used in the description of some embodiments or the related art. Obviously, the accompanying drawings in the description below are merely some embodiments of the present disclosure. For those of ordinary skill in the art, other accompanying drawings may be obtained based on these accompanying drawings without any creative efforts.

FIG. 1 is a structural schematic view of a carrier boat provided in some embodiments of the present disclosure.

FIG. 2 is an enlarged structural schematic view of a structure at a circle A shown in FIG. 1.

Explanation of reference signs: 1—boat body; 2—front flow homogenizing plate; 3—rear flow homogenizing plate; 4—to-be-processed component; 5—placement chamber; 6—first blocking member.

### DETAILED DESCRIPTION

The technical solutions in some embodiments of the present disclosure may be clearly and completely described in conjunction with accompanying drawings. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure. In the description of the present disclosure, the directions or positional relationships indicated by the terms, “center”, “up”, “down”, “left”, “right”, “vertical”, “horizontal”, “inside”, “outside”, etc. are based on the methods or positional relationships shown in the accompanying drawings. It is only intended to facilitate the description of the embodiments of the present disclosure and simplify the description, but does not indicate or imply that the device or the element referred to must have a specific orientation, be constructed and operated in a specific orientation. Therefore, it cannot be understood as a limitation on the embodiments of the present disclosure. The terms “first”, “second”, and “third” in the present disclosure are only configured to describe purposes and cannot be understood as indicating or implying relative importance. In addition, the technical features involved in different embodiments described below can be combined with each other as long as they do not conflict.

The technical problem to be solved by the present disclosure is that in related art, as a placement chamber becomes larger and more monocrystalline silicon cell sheets are loaded into the carrier boat, the excess reaction source directly enters the carrier boat carrying the monocrystalline silicon cell sheets from the spray plate, which leads to localized areas with too much reaction source and some areas of the monocrystalline silicon cell sheets not receiving the aluminum oxide thin film deposition, thereby resulting in low photoelectric conversion efficiency.

### Example 1

This example provides a carrier boat. The carrier boat includes a boat body 1, a front flow homogenizing plate 2, and a rear flow homogenizing plate 3.

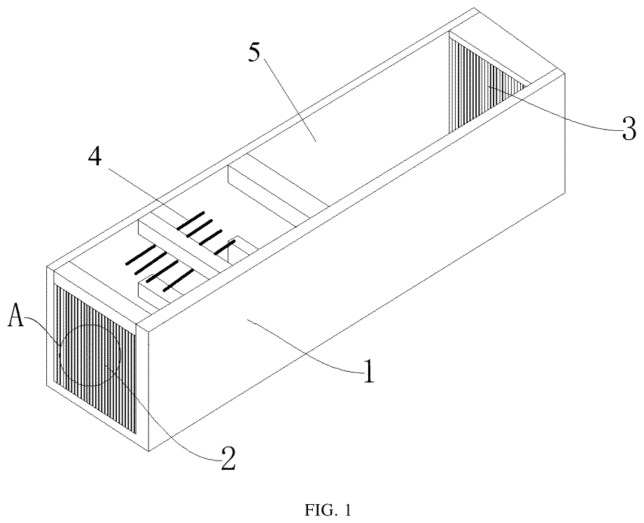

As shown in FIG. 1, the boat body 1 defines a placement chamber 5, and each of two opposite ends of the placement chamber 5 defines an opening. The placement chamber 5 is configured to accommodate to-be-processed components 4 that are spaced apart, and the to-be-processed components 4 are monocrystalline silicon cell sheets. The front flow homogenizing plate 2 is disposed at a left opening of the placement chamber 5 of the boat body 1, so as to fill or cover the left opening of the placement chamber 5. The rear flow homogenizing plate 3 is disposed at a right opening of the placement chamber 5 of the boat body 1, so as to fill or cover the right opening of the placement chamber 5.

In some embodiments, multiple partition rails are disposed in the placement chamber 5 of the boat body 1, so as to divide the placement chamber 5 into multiple reaction stations, and the monocrystalline silicon cell sheets are disposed in the reaction stations. The number of the reaction stations may be three, five, seven, etc., and the specific quantity of the reaction stations may be set according to usage requirements.

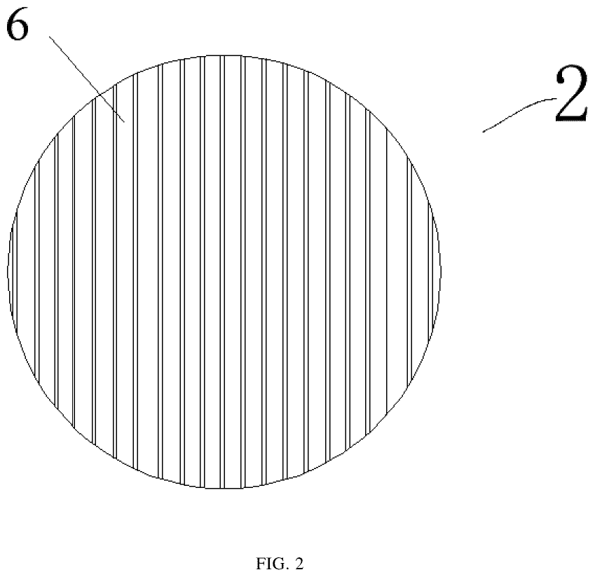

In some embodiments, as shown in FIGS. 1 and 2, the front flow homogenizing plate 2 is composed of multiple front blocking members that are densely arranged, a first gap is defined between two adjacent front blocking members. The front blocking members are also called first blocking members 6. Each front blocking member is thin strip-shaped, and parallel to a height direction of the boat body 1 and placement directions of the monocrystalline silicon cell sheets, so that the first gap between adjacent front blocking members is communicated with a second gap between adjacent to-be-processed components 4. Therefore, the delivery gas carrying the reaction source can enter the second gap through the first gap, so as to coat the monocrystalline silicon cell sheets. A thickness of the thin strip-shaped front blocking member ranges from 1 mm to 2 mm, and the thin strip-shaped front blocking member is very thin and does not obstruct the flow of the gas. A width of the second gap is less than that of the first gap.

Similarly, the rear flow homogenizing plate 3 is composed of multiple rear blocking members that are densely arranged at equal intervals. Each rear blocking member is also thin strip-shaped. The thin strip-shaped rear blocking members are parallel to the height direction of the boat body 1 and the placement directions of the monocrystalline silicon cell sheets, so that a third gap between two adjacent rear blocking members is communicated with the second gap between adjacent to-be-processed components 4. Therefore, the delivery gas carrying the reaction source can enter the third gap through the second gap, so that the gas inside the boat body 1 can flow through the third gap. The thickness of the thin strip-shaped rear blocking member ranges from 1 mm to 2 mm, and the thin strip-shaped rear blocking member is very thin and does not obstruct the flow of the gas. A width of the third gap is greater than that of the second gap.

In some embodiments, the specific quantity of the front and rear blocking members may be set according to specific usage requirements.

During the coating process, the boat body 1 is placed in a coating reaction chamber. A reaction source is carried by nitrogen gas, and delivered into a spraying plate through a gas pipe from a source container. The spraying plate is disposed on a side of the front flow homogenizing plate 2 that is away from the placement chamber 5, and the front blocking members are disposed close to a spraying port of the spraying plate. The reaction gas sprayed by the spraying plate enters the boat body 1 after first flowing through the front flow homogenizing plate 2 that is located at the front of the boat body 1. Since the front flow homogenizing plate 2 is composed of multiple front blocking members that are densely arranged at equal intervals, and the front blocking members are parallel to the height direction of the boat body 1 and the placement directions of the monocrystalline silicon cell sheets, the front flow homogenizing plate 2 is able to uniformly re-distribute the gas carrying the reaction source through the first gaps between adjacent front blocking members, so that re-distributed gas flows into the boat body 1. Therefore, the gas carrying the reaction source that flows into the boat body 1 can flow uniformly and parallel to the surfaces of the cell sheets, thus preventing excess reaction source from entering the boat body 1 directly from the spraying plate, as the reaction chamber becomes larger and more monocrystalline silicon cell sheets are loaded into the boat body 1. This could otherwise lead to localized areas with too much reaction source and some areas of the monocrystalline silicon cell sheets not receiving the aluminum oxide thin film deposition, thereby resulting in low photoelectric conversion efficiency.

The front flow homogenizing plate 2 is composed of elongated strips that are arranged densely, which can effectively prevent the gas carrying the reaction source from being blocked by the front flow homogenizing plate 2 when the gas carrying the reaction source flows into the boat body 1 in a direction parallel to a surface of the boat body 1. At the same time, because the boat body 1 is close to a spraying plane, the monocrystalline silicon cell sheets inside the boat body 1 are also closer to the spraying plane. The second gap between the monocrystalline silicon cell sheets is less than the first gap between the thin strip-shaped front blocking members of the front flow homogenizing plate 2. When the gas carrying the reaction source that is sprayed from the spraying plane directly sprays the monocrystalline silicon cell sheets, the monocrystalline silicon cell sheets can block the airflow. In this case, disposing the front flow homogenizing plate 2 can allow the gas carrying the reaction source to have time to buffer. A strip-shaped direction or a length extending direction of the front flow homogenizing plate 2 is parallel to length extending directions of the monocrystalline silicon cell sheets, which can stabilize the airflow direction, so that the gas flows parallel to the surfaces of the monocrystalline silicon cell sheets, thereby achieving uniform and stable coating process.

Due to the increasing length of the boat body 1 carrying the monocrystalline silicon cell sheets, the tail end of the boat body 1 and the monocrystalline silicon cell sheets have moved closer to the tail end of the coating reaction chamber. In the related art, because the tail end of the boat body 1 is close to the air-guiding duct and the pump tube that are connected to the vacuum system, the pumping speed at the tail end of the boat body 1 is too fast. Furthermore, the air-guiding duct is a curved exhaust or suction device. An air exhaust port of the air-guiding duct has a decreasing diameter, which causes the airflow at the tail end to no longer be in a parallel airflow state. The tail end of the boat body 1 carries the cell sheets. A shape of an inner wall leads to a locally unstable and non-parallel airflow field at the tail, which affects the deposition of the reaction source on the cell sheets, causing insufficient source deposition in certain areas of the cell sheets, thereby affecting the generation of the aluminum oxide film and impacting the photoelectric conversion efficiency. In the present disclosure, the rear flow homogenizing plate 3 is disposed at the tail end of the boat body 1. The rear flow homogenizing plate 3 is also composed of multiple rear blocking members that are densely arranged at equal intervals. The rear blocking members are disposed parallel to the height direction of the boat body 1 and the placement direction of the monocrystalline silicon cell sheets, so as to stabilize the airflow at the tail end of the boat body 1. Therefore, the gas carrying the reaction source can flow uniformly and parallel to the surfaces of the monocrystalline silicon cell sheets when flowing through the tail end of the boat body 1, thereby obtaining a passivation film with a better quality and improving the conversion efficiency of the cell sheets.

In some embodiments, the rear blocking members in the rear flow homogenizing plate 3 may also be inclined relative to a plane where the monocrystalline silicon cell sheets are located.

In some embodiments, a side of the rear flow homogenizing plate 3, close to the front flow homogenizing plate 2, may also be slope-shaped. Alternatively, a side of the rear flow homogenizing plate 3, away from the front flow homogenizing plate 2, may also be slope-shaped. Alternatively, both sides of the rear flow homogenizing plate 3 may be slope-shaped.

In some embodiments, in a direction from the front flow homogenizing plate 2 to the rear flow homogenizing plate 3, a width of the rear flow homogenizing plate 3 is greater than that of the front flow homogenizing plate 2. Because the width of the rear flow homogenizing plate 3 is greater than that of the front flow homogenizing plate 2, the pressure drop of the various reaction stations in the placement chamber 5 of the boat body 1 is equal, thus better stabilizing the airflow at the tail end of the boat body 1 by the rear flow homogenizing plate 3.

In some embodiments, the density of the second blocking members in the rear flow homogenizing plate 3 is disposed from dense at the center to sparse towards the periphery. Since the rear flow homogenizing plate 3 is disposed close to the end exit of the boat body 1 and close to the vacuum device at the tail end of the inner chamber, the vacuum device at the tail end extracts the gas in an annular pattern. Because the gas is extracted in an annular pattern, there is a difference in gas flow velocity distribution between the center and the periphery. Therefore, by setting the density of the second blocking members in the rear flow homogenizing plate 3 from dense at the center to sparse towards the periphery, the difference in gas flow velocity can be compensated accordingly through the density adjustments of the second blocking members.

In some embodiments, the rear flow homogenizing plate 3 may be formed by multiple interconnected flow homogenizing sub-plates. The densities of the second blocking members of the flow homogenizing sub-plates are different. During use, the density of the second blocking members of the rear flow homogenizing plate 3 can be adjusted by replacing the flow homogenizing sub-plates.

In some embodiments, more than two flow homogenizing sub-plates setting positions are disposed in the rear flow homogenizing plate 3, and the flow homogenizing sub-plates setting positions are configured to accommodate the flow homogenizing sub-plates. Each flow homogenizing sub-plate may have blocking members that are arranged with different densities or shapes. Different flow homogenizing sub-plates can be selected according to requirements.

Generally, the smaller the density of the blocking members, the more pronounced the pressure drop of the airflow. Moreover, because the extraction structure at the tail end is an annular gradient structure that is ultimately connected to a circular extraction end, the airflow at the center experiences a more pronounced pressure drop compared with the airflow at the periphery. When the rear flow homogenizing plate 3 includes multiple flow homogenizing sub-plates, because the airflow between processing components is relatively uniform, the flow homogenizing sub-plates close to the processing components use the blocking members with the same density, while the flow homogenizing sub-plates close to the extraction end use the blocking members with different density distributions.

For the sake of manufacturing convenience and cost considerations, the flow homogenizing sub-plates may be manufactured using conventional methods. The flow homogenizing sub-plate that only has blocking members at the center position may be manufactured. When this flow homogenizing sub-plate is used in conjunction with other flow homogenizing sub-plates, the pressure drop at the center position can be reduced, thereby offsetting the difference that the pressure drop at the center is greater than that at the periphery, and the difference is caused by the connection to the extraction end.

### Example 2

This example provides a processing apparatus, including a spraying device and the carrier boat in the example 1. The spraying device is disposed on a side of the front flow homogenizing plate 2 inside the carrier boat. During the coating process, the boat body 1 is placed in the coating reaction chamber of the processing apparatus. The reaction source is carried by carried by the nitrogen gas, and delivered into the spraying plate of the spraying device through the gas pipe from the source container. The spraying plate is disposed on the side of the front flow homogenizing plate 2 that is away from the placement chamber 5, and the front blocking members are disposed close to the spraying port of the spraying plate. The reaction gas sprayed by the spraying plate enters the boat body 1 after flowing through the front flow homogenizing plate 2, so as to perform the coating process on the monocrystalline silicon cell sheets inside the boat body 1, and then flows out of the boat body 1 through the rear flow homogenizing plate 3.

### Example 3

This example provides a method for controlling the pressure drop in the carrier boat. By adjusting the density of the second blocking members of the rear flow homogenizing plate 3 in the carrier boat as described in the example 1, the pressure drop in the carrier boat is controlled.

In some embodiments, adjusting the density of the second blocking members of the rear flow homogenizing plate 3 in the carrier boat includes replacing the flow homogenizing sub-plate of the rear flow homogenizing plate 3 or directly replacing entire rear flow homogenizing plate 3.

In some embodiments, the pressure drop in the carrier boat may also be controlled by adjusting the thickness of the rear flow homogenizing plate 3 or the thickness of the second blocking member. The thicker the second blocking member, the more pronounced the airflow pressure drop.

The carrier boat, the processing apparatus, and the method for controlling the pressure drop in the carrier boat in the present disclosure have the following advantages.

First, the present disclosure provides the carrier boat including the boat body and the front flow homogenizing plate. The boat body defines the placement chamber with openings at two opposite ends, and the placement chamber is configured to accommodate a plurality of to-be-processed components that are spaced apart. The front flow homogenizing plate is disposed in an opening on an end of the placement chamber of the boat body, so as to fill the opening of the placement chamber of the boat body. The front flow homogenizing plate includes a plurality of first blocking members that are spaced apart, and the first gap between two adjacent first blocking members is communicated with the second gap between two adjacent to-be-processed components.

In the carrier boat, the placement chamber with openings at two opposite ends is defined inside the boat body, and the front flow homogenizing plate is disposed in the opening on an end of the placement chamber. When the reaction source carried by nitrogen gas flows through the front flow homogenizing plate from the source container, due to the front flow homogenizing plate including multiple front blocking members that are densely arranged at equal intervals, the front flow homogenizing plate is able to uniformly re-distribute the gas carrying the reaction source through the first gaps between adjacent front blocking members, so that re-distributed gas flows into the boat body. Therefore, the gas carrying the reaction source that flows into the boat body can flow uniformly and parallel to the surfaces of the to-be-processed components, thus preventing excess reaction source from entering the boat body directly, as the reaction chamber becomes larger and more to-be-processed components are loaded into the boat body. This could otherwise lead to localized areas with too much reaction source and some areas of the to-be-processed components not receiving the aluminum oxide thin film deposition, thereby resulting in low photoelectric conversion efficiency.

Second, the present disclosure further provides a processing apparatus (coating device). The processing apparatus further includes the rear flow homogenizing plate, and the rear flow homogenizing plate is disposed in the opening on the other end of the placement chamber of the boat body. The rear flow homogenizing plate is disposed at the tail end of the coating reaction chamber. The rear flow homogenizing plate includes rear blocking members that are arranged at equal intervals. The third gap between two adjacent rear blocking members is communicated with the second gap between two adjacent to-be-processed components.

In the processing apparatus (coating device), the rear flow homogenizing plate is disposed at the tail end of the boat body, and the rear flow homogenizing plate is also composed of multiple rear blocking members that are densely arranged at equal intervals. The rear blocking members are parallel to the height direction of the boat body and parallel to the placement directions of the monocrystalline silicon cell sheets, so as to stabilize the airflow at the tail end of the boat body. Therefore, the gas carrying the reaction source can flow uniformly and parallel to the surfaces of the monocrystalline silicon cell sheets when flowing through the tail end of the boat body, thereby obtaining a passivation film with better quality and improving conversion efficiency of the cell sheet.

The above embodiments or examples are merely provided as illustrations for clarity and are not limitations on the implementation methods. For those skilled in the art, other different forms of changes or variations can be made based on the above description. It is neither necessary nor possible to exhaustively enumerate all possible implementation methods. Obvious modifications or variations derived from this still fall within the protection scope created by the present disclosure.

1. A carrier boat, comprising:
a boat body, defining a placement chamber with openings at two opposite ends, wherein the placement chamber is configured to accommodate a plurality of to-be-processed components that are spaced apart; and
a front flow homogenizing plate, disposed in an opening on an end of the placement chamber of the boat body, so as to fill the opening of the placement chamber of the boat body;
wherein the front flow homogenizing plate comprises a plurality of first blocking members that are spaced apart, and a first gap between two adjacent first blocking members is communicated with a second gap between two adjacent to-be-processed components.

2. The carrier boat as claimed in claim 1, further comprising a rear flow homogenizing plate, wherein the rear flow homogenizing plate is disposed in an opening on another end of the placement chamber of the boat body, and the rear flow homogenizing plate comprises a plurality of second blocking members that are spaced apart.

3. The carrier boat as claimed in claim 2, wherein in a direction from the front flow homogenizing plate to the rear flow homogenizing plate, a width of the rear flow homogenizing plate is greater than that of the front flow homogenizing plate.

4. The carrier boat as claimed in claim 3, wherein the second blocking members are inclined relative to a plane where the to-be-processed components are located.

5. The carrier boat as claimed in claim 3, wherein the rear flow homogenizing plate comprises a plurality of interconnected flow homogenizing sub-plates, and the second blocking members in any one of the plurality of flow homogenizing sub-plates have different density.

6. The carrier boat as claimed in claim 3, wherein density of the second blocking members in the rear flow homogenizing plate is disposed from dense at a center to sparse towards periphery.

7. The carrier boat as claimed in claim 4, wherein a width of a third gap between two adjacent second blocking members is greater than that of the second gap.

8. The carrier boat as claimed in claim 1, wherein a width of the second gap is less than that of the first gap.

9. The carrier boat as claimed in claim 8, wherein a plane where any one of the plurality of first blocking members is located is parallel to a plane where any one of plurality of to-be-processed components is located.

10. A processing apparatus, comprising:
a spraying device; and
a carrier boat, comprising:
a boat body, defining a placement chamber with openings at two opposite ends, wherein the placement chamber is configured to accommodate a plurality of to-be-processed components that are spaced apart; and
a front flow homogenizing plate, disposed in an opening on an end of the placement chamber of the boat body, so as to fill the opening of the placement chamber of the boat body; wherein the front flow homogenizing plate comprises a plurality of first blocking members that are spaced apart, and a first gap between two adjacent first blocking members is communicated with a second gap between two adjacent to-be-processed components;
wherein the spraying device is disposed on a side of the front flow homogenizing plate in the carrier boat.

11. The processing apparatus as claimed in claim 10, wherein the carrier boat further comprising a rear flow homogenizing plate, wherein the rear flow homogenizing plate is disposed in an opening on the other end of the placement chamber of the boat body, and the rear flow homogenizing plate comprises a plurality of second blocking members that are spaced apart.

12. The processing apparatus as claimed in claim 11, wherein in a direction from the front flow homogenizing plate to the rear flow homogenizing plate, a width of the rear flow homogenizing plate is greater than that of the front flow homogenizing plate.

13. The processing apparatus as claimed in claim 12, wherein the second blocking members are inclined relative to a plane where the to-be-processed components are located.

14. The processing apparatus as claimed in claim 12, wherein the rear flow homogenizing plate comprises a plurality of interconnected flow homogenizing sub-plates, and the second blocking members in any one of the plurality of flow homogenizing sub-plates have different density.

15. The processing apparatus as claimed in claim 12, wherein density of the second blocking members in the rear flow homogenizing plate is disposed from dense at a center to sparse towards periphery.

16. The processing apparatus as claimed in claim 13, wherein a width of a third gap between two adjacent second blocking members is greater than that of the second gap.

17. The processing apparatus as claimed in claim 10, wherein a width of the second gap is less than that of the first gap.

18. The processing apparatus as claimed in claim 17, wherein a plane where any one of the plurality of first blocking members is located is parallel to a plane where any one of plurality of to-be-processed components is located.

19. A method for controlling pressure drop in a carrier boat, comprising:
providing a carrier boat, wherein the carrier boat comprises:
a boat body, defining a placement chamber with openings at two opposite ends, wherein the placement chamber is configured to accommodate a plurality of to-be-processed components that are spaced apart; and
a front flow homogenizing plate, disposed in an opening on an end of the placement chamber of the boat body, so as to fill the opening of the placement chamber of the boat body; wherein the front flow homogenizing plate comprises a plurality of first blocking members that are spaced apart, and a first gap between two adjacent first blocking members is communicated with a second gap between two adjacent to-be-processed components; and
a rear flow homogenizing plate, disposed in an opening on the other end of the placement chamber of the boat body, wherein the rear flow homogenizing plate comprises a plurality of second blocking members that are spaced apart; and
adjusting density of the second blocking members, or a thickness of the rear flow homogenizing plate and a thickness of each second blocking member of the rear flow homogenizing plate, so as to control pressure drop in the carrier boat.

20. The method as claimed in claim 19, wherein in a direction from the front flow homogenizing plate to the rear flow homogenizing plate, a width of the rear flow homogenizing plate is greater than that of the front flow homogenizing plate.
